(19) United States
(12) Patent Application Publication
(10) Pub. No.: US 2024/0275363 A1
(43) Pub. Date: Aug. 15, 2024

(54) ACOUSTIC WAVE DEVICE WITH AN EFFICIENT STRUCTURE, A RADIO FREQUENCY MODULE, AND A MOBILE DEVICE INCLUDING THE SAME

(71) Applicant: Skyworks Solutions, Inc., Irvine, CA (US)

(72) Inventors: Kurt George Steiner, Orlando, FL (US); Alan Sangone Chen, Leesburg, FL (US); Yosuke Hamaoka, Suita-Shi (JP); Benjamin Paul Abbott, Irvine, CA (US)

(21) Appl. No.: 18/426,707

(22) Filed: Jan. 30, 2024

Related U.S. Application Data
(60) Provisional application No. 63/484,793, filed on Feb. 14, 2023.

(51) Int. Cl. H03H 9/70; H03H 9/02; H03H 9/05; H03H 9/64

(52) U.S. Cl. CPC H03H 9/706; H03H 9/02992; H03H 9/0576; H03H 9/6453

(57) ABSTRACT

Aspects and embodiments disclosed herein include an acoustic wave device comprising a substrate, a pair of inter-digital transducer (IDT) electrodes formed on the substrate, each of the pair of IDT electrodes including a bus bar and a plurality of fingers extending from the bus bar, fingers of one IDT electrode arranged interleaved with fingers of the other IDT electrode, each of the bus bars of the pair of IDT electrodes having a slotted portion configured on an upper surface of the bus bars opposite to a lower surface contacting the substrate such that at least one hollow within each of the bus bars is opened at least at the upper surface of each of the bus bars, and a dielectric film covering the pair of IDT electrodes, at least a portion of the dielectric film filling in the at least one hollow of each of the bus bars.

### CROSS-REFERENCE TO RELATED APPLICATIONS

This application claims priority under 35 U.S.C. § 119 (e) to U.S. Provisional Patent Application Ser. No. 63/484,793, titled “ACOUSTIC WAVE DEVICE WITH AN EFFICIENT STRUCTURE, A RADIO FREQUENCY MODULE, AND A MOBILE DEVICE INCLUDING THE SAME,” filed Feb. 14, 2023, the entire content of which is incorporated herein by reference for all purposes.

### BACKGROUND

### Field

Embodiments of the invention relate to electronic systems, and in particular, to a filter for use in radio frequency (RF) electronics.

### Description of the Related Technology

Filters are used in radio frequency (RF) communication systems to allow signals to pass through at discreet frequencies but reject any frequency outside of the specified range. An acoustic wave filter, which is used widely in the wireless communication field, can include a plurality of resonators arranged to filter a radio frequency signal. Example acoustic wave filters include surface acoustic wave (SAW) filters and/or bulk acoustic wave (BAW) filters. A film bulk acoustic resonator (FBAR) filter is an example of a BAW filter. Acoustic wave filters can be implemented in radio frequency electronic systems. For instance, filters in a radio frequency front end of a mobile phone can include acoustic wave filters. A plurality of acoustic wave filters can be arranged as a multiplexer. For example, two surface acoustic wave filters can be arranged as a duplexer.

Examples of RF communication systems with one or more filter module include, but are not limited to, mobile phones, tablets, base stations, network access points, customer-premises equipment (CPE), laptops, and wearable electronics. For example, in wireless devices that communicate using a cellular standard, a wireless local area network (WLAN) standard, and/or any other suitable communication standard, a power amplifier can be used for RF signal amplification. An RF signal can have a frequency in the range of about 30 kHz to 300 GHz, such as in the range of about 410 MHz to about 7.125 GHz for certain communications standards.

### SUMMARY

In accordance with one aspect, there is provided an acoustic wave device. The acoustic wave device comprises a substrate, a pair of inter-digital transducer (IDT) electrodes formed on the substrate, each of the pair of IDT electrodes including a bus bar and a plurality of fingers extending from the bus bar, a respective finger of one IDT electrode arranged interleaved with respective fingers of the other IDT electrode, each of the bus bars of the pair of IDT electrodes having a slotted portion configured on an upper surface of the bus bars opposite to a lower surface contacting the substrate such that at least one hollow within each of the bus bars is opened at least at the upper surface of each of the bus bars, and a dielectric film covering the pair of IDT electrodes, at least a portion of the dielectric film filling in the at least one hollow of each of the bus bars.

In some embodiments, the slotted portion includes a plurality of slots extending in parallel, and each of the plurality of slots extends in a direction same as an extending direction of the plurality of fingers.

In some embodiments, the slotted portion includes a plurality of slots extending in parallel, and each of the plurality of slots extends in a direction orthogonal to an extending direction of the plurality of fingers.

In some embodiments, a distance between the adjacent slots of the plurality of slots is substantially identical to a width of each of the plurality of fingers.

In some embodiments, a width of each of the plurality of slots is substantially identical to a pitch distance of respective fingers of the pair of IDT electrodes.

In some embodiments, a remaining portion of the upper surface of each of the bus bars other than the slotted portion is configured to be a part of a line with a same width of each of the plurality of fingers.

In some embodiments, the remaining portion of the upper surface of each of the bus bars is an outline of each of the bus bars.

In some embodiments, the slotted portion extends from the upper surface to the lower surface of each of the bus bars such that at least a portion of the dielectric film contacts with the substrate.

In some embodiments, the at least one hollow of the slotted portion is grooved in square shape within each of the bus bars.

In some embodiments, the slotted portion is a single pulse-shaped slot with a same width of each of the plurality of fingers and with a gap corresponding to a pitch distance of respective fingers of the pair of IDT electrodes therebetween.

In some embodiments, at least a portion of the dielectric film fills in a gap between the plurality of fingers of each of the pair of IDT electrodes, such that the dielectric film has a planar surface throughout the pair of IDT electrodes.

In some embodiments, the dielectric film is formed of silicon dioxide (SiO²).

In accordance with another aspect, there is provided a radio frequency module. The radio frequency module comprises a packaging board configured to receive a plurality of components, and an acoustic wave device implemented on the packaging board, the acoustic wave device including a substrate, a pair of inter-digital transducer (IDT) electrodes formed on the substrate, each of the pair of IDT electrodes including a bus bar and a plurality of fingers extending from the bus bar, a respective finger of one IDT electrode arranged interleaved with respective fingers of the other IDT electrode, each of the bus bars of the pair of IDT electrodes having a slotted portion configured on an upper surface of the bus bars opposite to a lower surface contacting the substrate such that at least one hollow within each of the bus bars is opened at least at the upper surface of each of the bus bars, and a dielectric film covering the pair of IDT electrodes, at least a portion of the dielectric film filling in the at least one hollow of each of the bus bars.

In some embodiments, the radio frequency module is a front-end module.

In some embodiments, the slotted portion includes a plurality of slots extending in parallel, and each of the plurality of slots extends in a direction same as an extending direction of the plurality of fingers.

In some embodiments, the slotted portion includes a plurality of slots extending in parallel, and each of the plurality of slots extends in a direction orthogonal to an extending direction of the plurality of fingers.

In some embodiments, a distance between the adjacent slots of the plurality of slots is substantially identical to a width of each of the plurality of fingers.

In some embodiments, a width of each of the plurality of slots is substantially identical to a pitch distance of respective fingers of the pair of IDT electrodes.

In some embodiments, a remaining portion of the upper surface of each of the bus bars other than the slotted portion is configured to be a part of a line with a same width of each of the plurality of fingers.

In some embodiments, the remaining portion of the upper surface of each of the bus bars is an outline of each of the bus bars.

In some embodiments, the slotted portion extends from the upper surface to the lower surface of each of the bus bars such that at least a portion of the dielectric film contacts with the substrate.

In some embodiments, the at least one hollow of the slotted portion is grooved in square shape within each of the bus bars.

In some embodiments, the slotted portion is a single pulse-shaped slot with a same width of each of the plurality of fingers and with a gap corresponding to a pitch distance of respective fingers of the pair of IDT electrodes therebetween.

In some embodiments, at least a portion of the dielectric film fills in a gap between the plurality of fingers of each of the pair of IDT electrodes, such that the dielectric film has a planar surface throughout the pair of IDT electrodes.

In some embodiments, the dielectric film is formed of silicon dioxide (SiO₂).

In accordance with another aspect, there is provided a mobile device. The mobile device comprises an antenna configured to receive a radio frequency signal, and a front end system configured to communicate with the antenna, the front end system including an acoustic wave device having a substrate, a pair of inter-digital transducer (IDT) electrodes formed on the substrate, each of the pair of IDT electrodes including a bus bar and a plurality of fingers extending from the bus bar, a respective finger of one IDT electrode arranged interleaved with respective fingers of the other IDT electrode, each of the bus bars of the pair of IDT electrodes having a slotted portion configured on an upper surface of the bus bars opposite to a lower surface contacting the substrate such that at least one hollow within each of the bus bars is opened at least at the upper surface of each of the bus bars, and a dielectric film covering the pair of IDT electrodes, at least a portion of the dielectric film filling in the at least one hollow of each of the bus bars.

In some embodiments, the slotted portion includes a plurality of slots extending in parallel, and each of the plurality of slots extends in a direction same as an extending direction of the plurality of fingers.

In some embodiments, the slotted portion includes a plurality of slots extending in parallel, and each of the plurality of slots extends in a direction orthogonal to an extending direction of the plurality of fingers.

In some embodiments, a distance between the adjacent slots of the plurality of slots is substantially identical to a width of each of the plurality of fingers.

In some embodiments, a width of each of the plurality of slots is substantially identical to a pitch distance of respective fingers of the pair of IDT electrodes.

In some embodiments, a remaining portion of the upper surface of each of the bus bars other than the slotted portion is configured to be a part of a line with a same width of each of the plurality of fingers.

In some embodiments, the remaining portion of the upper surface of each of the bus bars is an outline of each of the bus bars.

In some embodiments, the slotted portion extends from the upper surface to the lower surface of each of the bus bars such that at least a portion of the dielectric film contacts with the substrate.

In some embodiments, the at least one hollow of the slotted portion is grooved in square shape within each of the bus bars.

In some embodiments, the slotted portion is a single pulse-shaped slot with a same width of each of the plurality of fingers and with a gap corresponding to a pitch distance of respective fingers of the pair of IDT electrodes therebetween.

In some embodiments, at least a portion of the dielectric film fills in a gap between the plurality of fingers of each of the pair of IDT electrodes, such that the dielectric film has a planar surface throughout the pair of IDT electrodes.

In some embodiments, the dielectric film is formed of silicon dioxide (SiO₂).

### BRIEF DESCRIPTION OF THE DRAWINGS

FIG. 1 is a schematic diagram of one embodiment of a mobile device;

FIG. 2A is a schematic diagram of a carrier aggregation system;

FIG. 2B is a schematic diagram of a carrier aggregation system;

FIG. 2C is a schematic diagram of a carrier aggregation system;

FIG. 2D is a schematic diagram of a carrier aggregation system;

FIG. 3A is a schematic block diagram of a module that includes a filter;

FIG. 3B is a schematic block diagram of a module that includes a filter;

FIG. 4 is an example of schematic diagram of acoustic wave device;

FIG. 5 is a sectional view of the acoustic wave device aligned along a single electrode finger;

FIG. 6 is a sectional view of the acoustic wave device aligned along a single electrode finger;

FIG. 7A is a schematic diagram of an example of a conventional acoustic wave device;

FIG. 7B is a schematic diagram of a cross-section of the acoustic wave device of FIG. 7A taken along the lines 7B-7B;

FIG. 8A is a schematic diagram of an example of an acoustic wave device according to an embodiment;

FIG. 8B is a schematic diagram of a cross-section of the acoustic wave device of FIG. 8A taken along the lines 8B-8B;

FIG. 9A is a schematic diagram of one embodiment of a packaged module;

FIG. 9B is a schematic diagram of a cross-section of the packaged module of FIG. 9A taken along the lines 9B-9B; and

FIG. 10 is a schematic diagram of one embodiment of a phone board.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

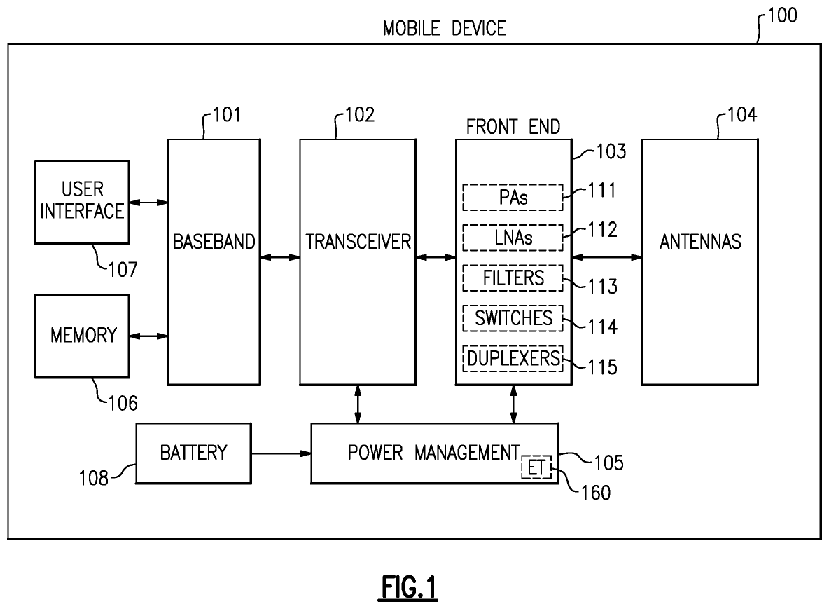

FIG. 1 is a schematic diagram of one example of a mobile device 100. The mobile device 100 includes a baseband system 101, a transceiver 102, a front end system 103, antennas 104, a power management system 105, a memory 106, a user interface 107, and a battery 108.

The mobile device 100 can be used communicate using a wide variety of communications technologies, including, but not limited to, 2G, 3G, 4G (including LTE, LTE-Advanced, and LTE-Advanced Pro), 5G, WLAN (for instance, Wi-Fi), WPAN (for instance, Bluetooth and ZigBee), WMAN (for instance, WiMax), and/or GPS technologies.

The transceiver 102 generates RF signals for transmission and processes incoming RF signals received from the antennas 104. It will be understood that various functionalities associated with the transmission and receiving of RF signals can be achieved by one or more components that are collectively represented in FIG. 1 as the transceiver 102. In one example, separate components (for instance, separate circuits or dies) can be provided for handling certain types of RF signals.

The front end system 103 aids in conditioning signals transmitted to and/or received from the antennas 104. In the illustrated embodiment, the front end system 103 includes power amplifiers (PAs) 111, low noise amplifiers (LNAs) 112, filters 113, switches 114, and duplexers 115. However, other implementations are possible.

For example, the front end system 103 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 100 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band and/or in different bands.

The antennas 104 can include antennas used for a wide variety of types of communications. For example, the antennas 104 can include antennas associated transmitting and/or receiving signals associated with a wide variety of frequencies and communications standards.

In certain implementations, the antennas 104 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 100 can operate with beamforming in certain implementations. For example, the front end system 103 can include phase shifters having variable phase controlled by the transceiver 102. Additionally, the phase shifters are controlled to provide beam formation and directivity for transmission and/or reception of signals using the antennas 104. For example, in the context of signal transmission, the phases of the transmit signals provided to the antennas 104 are controlled such that radiated signals from the antennas 104 combine using constructive and destructive interference to generate an aggregate transmit signal exhibiting beam-like qualities with more signal strength propagating in a given direction. In the context of signal reception, the phases are controlled such that more signal energy is received when the signal is arriving to the antennas 104 from a particular direction. In certain implementations, the antennas 104 include one or more arrays of antenna elements to enhance beamforming.

The baseband system 101 is coupled to the user interface 107 to facilitate processing of various user input and output (I/O), such as voice and data. The baseband system 101 provides the transceiver 102 with digital representations of transmit signals, which the transceiver 102 processes to generate RF signals for transmission. The baseband system 101 also processes digital representations of received signals provided by the transceiver 102. As shown in FIG. 1, the baseband system 101 is coupled to the memory 106 of facilitate operation of the mobile device 100.

The memory 106 can be used for a wide variety of purposes, such as storing data and/or instructions to facilitate the operation of the mobile device 100 and/or to provide storage of user information.

The power management system 105 provides a number of power management functions of the mobile device 100. The power management system 105 of FIG. 1 includes an envelope tracker 160. As shown in FIG. 1, the power management system 105 receives a battery voltage form the battery 108. The battery 108 can be any suitable battery for use in the mobile device 100, including, for example, a lithium-ion battery.

The mobile device 100 of FIG. 1 illustrates one example of an RF communication system that can include power amplifier(s) implemented in accordance with one or more features of the present disclosure. However, the teachings herein are applicable to RF communication systems implemented in a wide variety of ways.

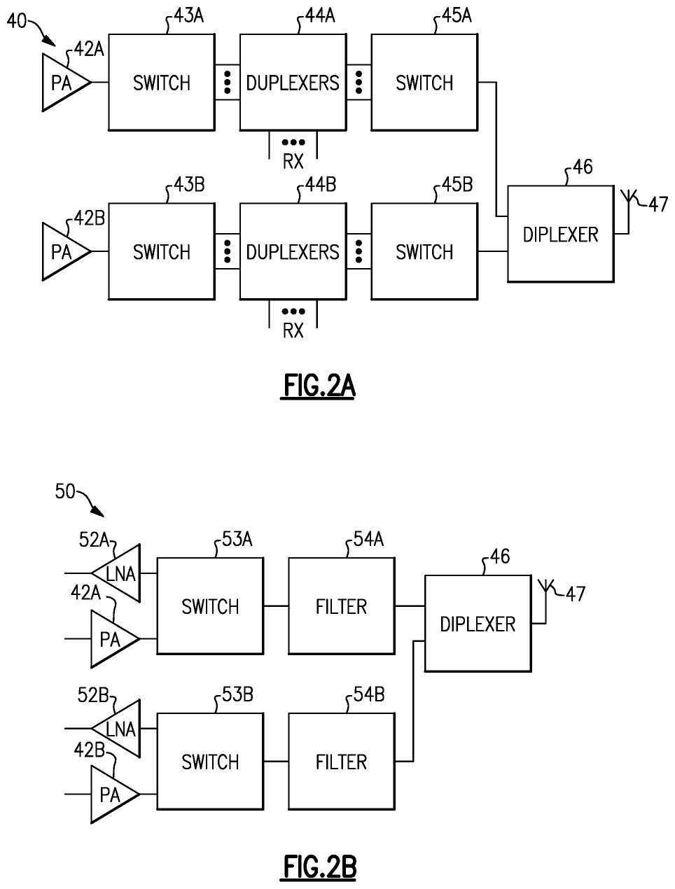

FIG. 2A is a schematic diagram of a carrier aggregation system 40. The illustrated carrier aggregation system 40 includes power amplifiers 42A and 42B, switches 43A and 43B, duplexers 44A and 44B, switches 45A and 45B, diplexer 46, and antenna 47. The power amplifiers 42A and 42B can each transmit an amplified RF signal associated with a different carrier. The switch 43A can be a band select switch. The switch 43A can couple an output of the power amplifier 42A to a selected duplexer of the duplexers 44A. Each of the duplexers can include a transmit filter and receive filter. Any of the filters of the duplexers 44A and 44B can be implemented in accordance with any suitable principles and advantages discussed herein. The switch 45A can couple the selected duplexer of the duplexers 44A to the diplexer 46. The diplexer 46 can combine RF signals provided by the switches 45A and 45B into a carrier aggregation signal that is transmitted by the antenna 47. The diplexer 46 can isolate different frequency bands of a carrier aggregation signal received by the antenna 47. The diplexers 46 is an example of a frequency domain multiplexer. Other frequency domain multiplexers include a triplexer. Carrier aggregation systems that include triplexers can process carrier aggregation signals associated with three carriers. The switches 45A and 45B and selected receive filters of the duplexers 44A and 44B can provide RF signals with the isolated frequency bands to respective receive paths.

FIG. 2B is a schematic diagram of a carrier aggregation system 50. The illustrated carrier aggregation system 50 includes power amplifiers 42A and 42B, low noise amplifiers 52A and 52B, switches 53A and 53B, filters 54A and 54B, diplexer 46, and antenna 47. The power amplifiers 42A and 42B can each transmit an amplified RF signal associated with a different carrier. The switch 53A can be a transmit/receive switch. The switch 53A can couple the filter 54A to an output of the power amplifier 42A in a transmit mode and to an input of the low noise amplifier 52A in a receive mode. The filter 54A and/or the filter 54B can be implemented in accordance with any suitable principles and advantages discussed herein. The diplexer 46 can combine RF signals from the power amplifiers 42A and 42B provided by the switches 53A and 53B into a carrier aggregation signal that is transmitted by the antenna 47. The diplexer 46 can isolate different frequency bands of a carrier aggregation signal received by the antenna 47. The switches 53A and 53B and the filters 54A and 54B can provide RF signals with the isolated frequency bands to respective low noise amplifiers 52A and 52B.

FIG. 2C is a schematic diagram of a carrier aggregation system 60 that includes multiplexers in signal paths between power amplifiers and an antenna. The illustrated carrier aggregation system 60 includes a low band path, a medium band path, and a high band path. In certain applications, a low band path can process radio frequency signals having a frequency of less than 1 GHz, a medium band path can process radio frequency signals having a frequency between 1 GHz and 2.2 GHz, and a high band path can process radio frequency signals having a frequency above 2.2 GHz.

A diplexer 46 can be included between RF signal paths and an antenna 47. The diplexer 46 can frequency multiplex radio frequency signals that are relatively far away in frequency. The diplexer 46 can be implemented with passive circuit elements having a relatively low loss. The diplexer 46 can combine (for transmit) and separate (for receive) carriers of carrier aggregation signals.

As illustrated, the low band path includes a power amplifier 42A configured to amplify a low band radio frequency signal, a band select switch 43A, and a multiplexer 64A. The band select switch 43A can electrically connect the output of the power amplifier 42A to a selected transmit filter of the multiplexer 64A. The selected transmit filter can be a band pass filter with pass band corresponding to a frequency of an output signal of the power amplifier 42A. The multiplexer 64A can include any suitable number of transmit filters and any suitable number of receive filters. One or more of the transmit filters and/or one or more of the receive filters can be implemented in accordance with any suitable principles and advantages discussed herein. The multiplexer 64A can have the same number of transmit filters as receive filters. In some instances, the multiplexer 64A can have a different number of transmit filters than receive filters.

As illustrated in FIG. 2C, the medium band path includes a power amplifier 42B configured to amplify a medium band radio frequency signal, a band select switch 43B, and a multiplexer 64B. The band select switch 43B can electrically connect the output of the power amplifier 42B to a selected transmit filter of the multiplexer 64B. The selected transmit filter can be a band pass filter with pass band corresponding to a frequency of an output signal of the power amplifier 42B. The multiplexer 64B can include any suitable number of transmit filters and any suitable number of receive filters. One or more of the transmit filters and/or one or more of the receive filters can be implemented in accordance with any suitable principles and advantages discussed herein. The multiplexer 64B can have the same number of transmit filters as receive filters. In some instances, the multiplexer 64B can have a different number of transmit filters than receive filters.

In the illustrated carrier aggregation system 60, the high band path includes a power amplifier 42C configured to amplify a high band radio frequency signal, a band select switch 43C, and a multiplexer 64C. The band select switch 43C can electrically connect the output of the power amplifier 42C to a selected transmit filter of the multiplexer 64C. The selected transmit filter can be a band pass filter with pass band corresponding to a frequency of an output signal of the power amplifier 42C. The multiplexer 64C can include any suitable number of transmit filters and any suitable number of receive filters. One or more of the transmit filters and/or one or more of the receive filters can be implemented in accordance with any suitable principles and advantages discussed herein. The multiplexer 64C can have the same number of transmit filters as receive filters. In some instances, the multiplexer 64C can have a different number of transmit filters than receive filters.

A select switch 65 can selectively provide a radio frequency signal from the medium band path or the high band path to the diplexer 46. Accordingly, the carrier aggregation system 60 can process carrier aggregation signals with either a low band and high band combination or a low band and medium band combination.

FIG. 2D is a schematic diagram of a carrier aggregation system 70 that includes multiplexers in signal paths between power amplifiers and an antenna. The carrier aggregation system 70 is like the carrier aggregation system 60 of FIG. 2C, except that the carrier aggregation system 70 includes switch-plexing features. Switch-plexing can be implemented in accordance with any suitable principles and advantages discussed herein.

Switch-plexing can implement on-demand multiplexing. Some radio frequency systems can operate in a single carrier mode for a majority of time (e.g., about 95% of the time) and in a carrier aggregation mode for a minority of the time (e.g., about 5% of the time). Switch-plexing can reduce loading in a single carrier mode in which the radio frequency system can operate for the majority of the time relative to a multiplexer that includes filters having a fixed connection at a common node. Such a reduction in loading can be more significant when there are a relatively larger number of filters included in multiplexer.

In the illustrated carrier aggregation system 70, duplexers 64B and 64C are selectively coupled to a diplexer 46 by way of a switch 75. The switch 75 is configured as a multi-close switch that can have two or more throws active concurrently. Having multiple throws of the switch 75 active concurrently can enable transmission and/or reception of carrier aggregation signals. The switch 75 can also have a single throw active during a single carrier mode. As illustrated, each duplexer of the duplexers 44A coupled to separate throws of the switch 75. Similarly, the illustrated duplexers 44B include a plurality of duplexers coupled to separate throws of the switch 75. Alternatively, instead of duplexers being coupled to each throw the switch 75 as illustrated in FIG. 2D, one or more individual filters of a multiplexer can be coupled to a dedicated throw of a switch coupled between the multiplexer and a common node. For instance, in some applications, such a switch could have twice as many throws as the illustrated switch 75.

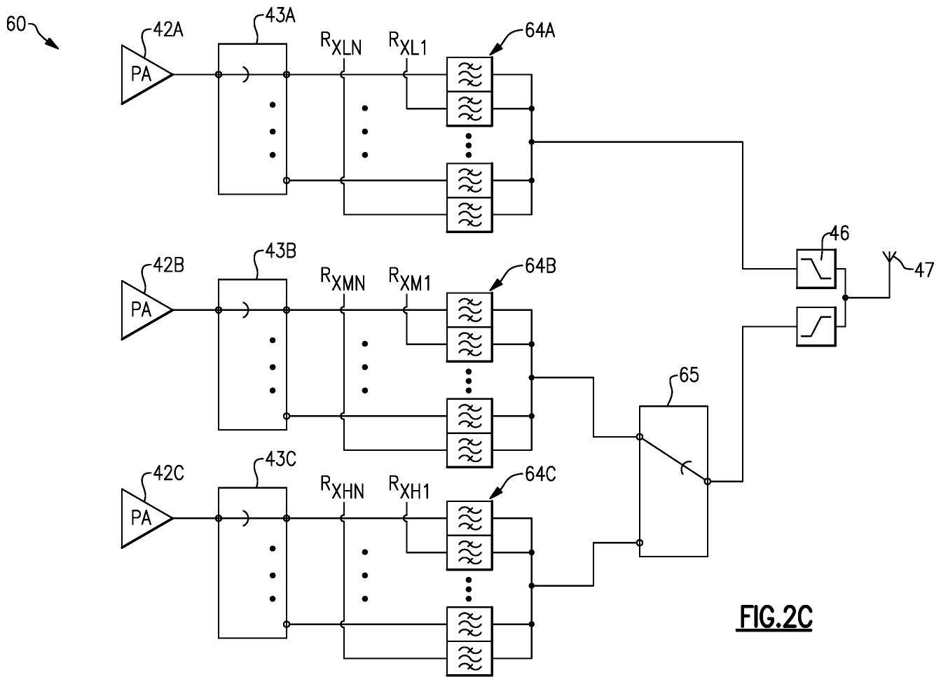

The filters discussed herein can be implemented in a variety of packaged modules. Some example packaged modules will now be discussed in which any suitable principles and advantages of the filters discussed herein can be implemented. FIGS. 3A and 3B are schematic block diagrams of illustrative packaged modules according to certain embodiments.

FIG. 3A is a schematic block diagram of a module 80 that includes a power amplifier 42, a switch 83, and filters 84 in accordance with one or more embodiments. The module 80 can include a package that encloses the illustrated elements. The power amplifier 42, a switch 83, and filters 84 can be disposed on a common packaging substrate. The packaging substrate can be a laminate substrate, for example. The switch 83 can be a multi-throw radio frequency switch. The switch 83 can electrically couple an output of the power amplifier 42 to a selected filter of the filters 84. The filters 84 can include any suitable number of surface acoustic wave filters. One or more filters of the filters 84 can be implemented in accordance with any suitable principles and advantages disclosed herein.

FIG. 3B is a schematic block diagram of a module 85 that includes power amplifiers 42A and 42B, switches 83A and 83B, and filters 84A and 84B in accordance with one or more embodiments, and an antenna switch 88. The module 85 is like the module 80 of FIG. 18A, except the module 85 includes an additional RF signal path and the antenna switch 88 arranged to selectively couple a signal from the filters 84A or the filters 84B to an antenna node. One or more filters of the filters 84A and/or 84B can be implemented in accordance with any suitable principles and advantages disclosed herein. The additional RF signal path includes an additional power amplifier 42B, and additional switch 83B, and additional filters 84B. The different RF signal paths can be associated with different frequency bands and/or different modes of operation (e.g., different power modes, different signaling modes, etc.).

In recent years, in the field of information communication devices such as mobile phones, acoustic wave devices having a comb-shaped IDT electrode formed on a surface of a piezoelectric substrate are used as circuit elements such as resonators, filters, and the like.

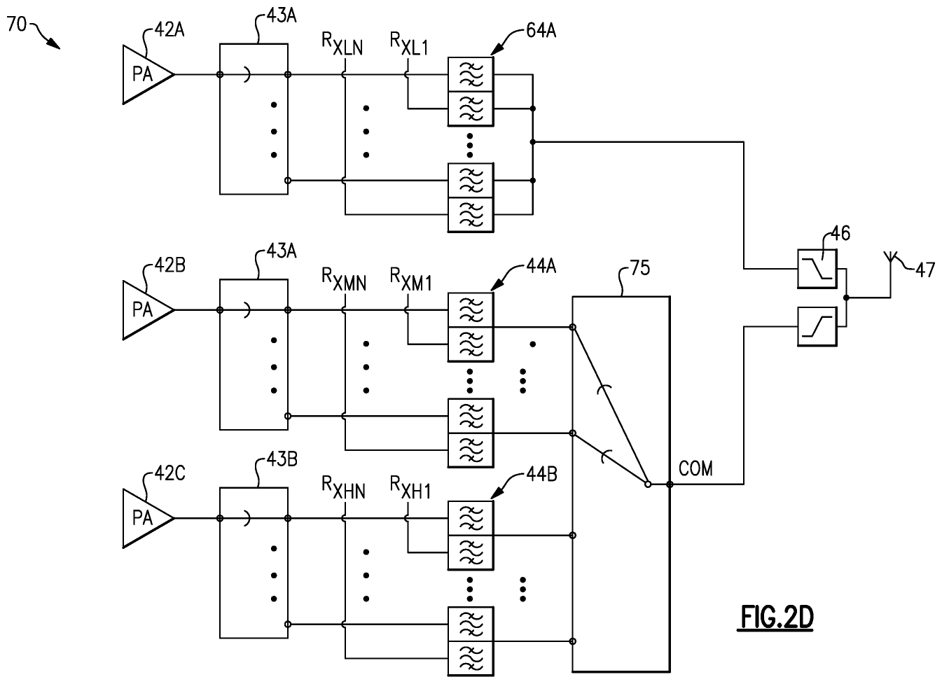

FIG. 4 shows examples of such acoustic wave devices. In FIG. 4, a top view of an acoustic wave device 400 is shown. In this description, the acoustic wave device 400 can be also referred to as a resonator. The acoustic wave device 400 is formed by arranging two IDT electrodes 402 and two reflectors 403 on a piezoelectric substrate 401. The IDT electrodes 402 each have a bus bar 411 and a plurality of electrode fingers 412 that extends from the bus bar 411. The respective electrode fingers 412 of each of the IDT electrodes 402 are arranged such that the electrode fingers 412 thereof are arranged interleaved with the respective electrode fingers 412 of the other IDT electrode 402. The reflectors 403 are arranged so as to interpose the IDT electrodes 402 therebetween.

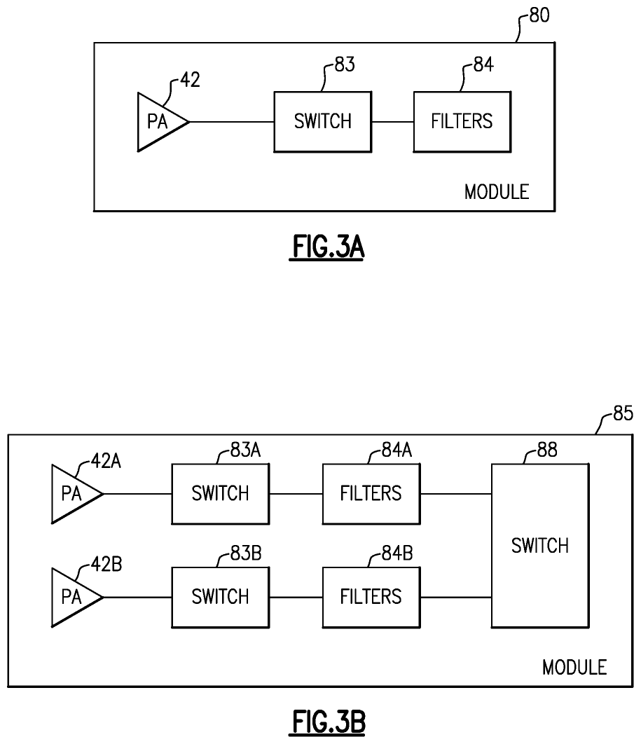

FIG. 5 is a sectional view of the acoustic wave device 500 aligned along a single electrode finger 412. In the acoustic wave device 500, propagation of an acoustic wave is concentrated to the coating film 504, thereby suppressing a high-order transverse mode wave which is an unnecessary wave.

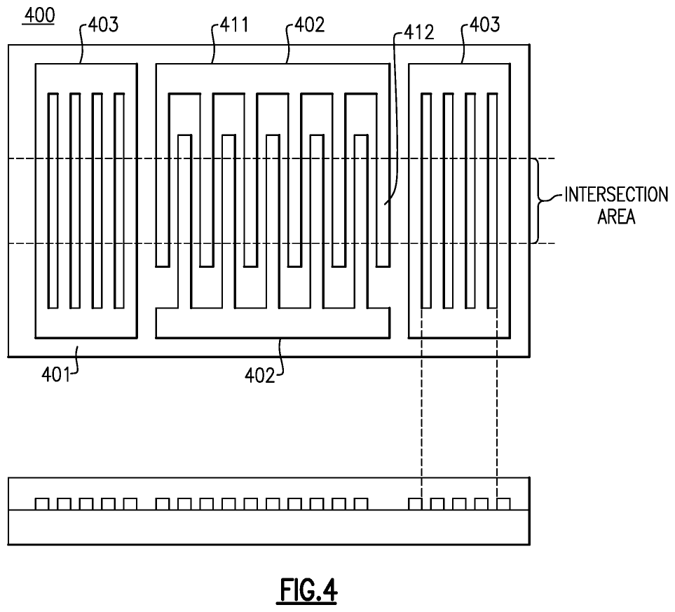

FIG. 6 is a sectional view of the acoustic wave device 600 aligned along a single electrode finger 412. An acoustic wave device 600 which is different from the acoustic wave device 500 in that a dielectric film 604 covers the piezoelectric substrate 401, the IDT electrodes 402, and the reflectors 403 Such that the Sur face thereof is flattened. In the acoustic wave device 600, the dielectric film 604 covers the piezoelectric substrate 601, thereby reducing frequency characteristic change of the acoustic wave device 600 depending on temperature.

Surface acoustic wave (SAW) structures utilize interdigitated metal structures on a piezoelectric substrate. The SAW device can then be made to be temperature compensated by depositing a thick silicon-dioxide (oxide) overcoat film. While overcoating the oxide is beneficial in accomplishing temperature compensation, it can degrade performance in terms of loss or quality factor. It is critical that the overcoat is free of voids, has low density seams and has minimum topography.

The current industry standard methods to achieve planarity include bias oxide deposition followed by chemical mechanical polishing (CMP). CMP is a process that removes materials by a combination of chemical and mechanical (or abrasive) actions to achieve highly smooth and planar material surfaces. The problem with this approach is that the film above the metal bus bars is much thicker than that in the active acoustic element and requires significant overhead, thereby resulting in longer CMP time. According to a conventional manufacturing procedure, while conducting the oxide deposition, inter-digital transducer (IDT) metal density variation can be a factor that determines the thickness of the oxide layer. More specifically, the particular region with the metal electrode may cause the oxide thickness variation compared to the other region without the metal electrode within a single resonator acoustic element.

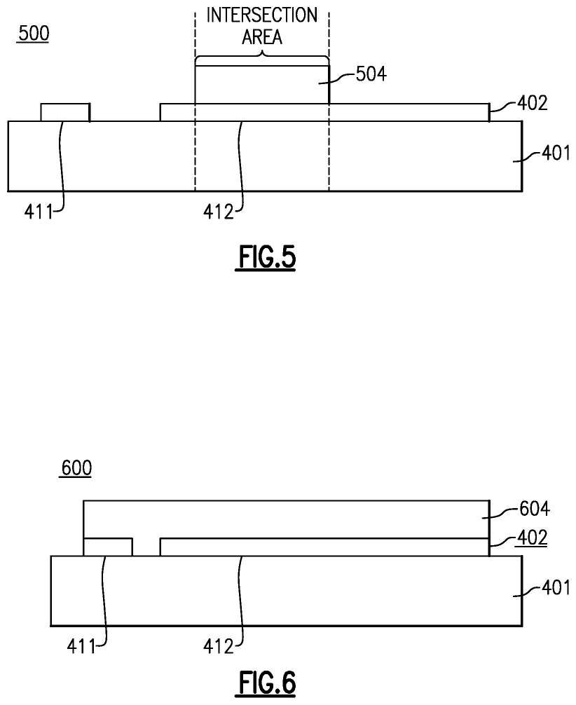

FIG. 7A is a schematic diagram of an example of a conventional acoustic wave device 700. FIG. 7B is a schematic diagram of a cross-section of the acoustic wave device of FIG. 7A taken along the lines 7B-7B. As shown in FIGS. 7A, 7B, the acoustic wave device 700 includes a substrate 702, a pair of inter-digital transducer (IDT) electrodes 704, and a dielectric film 710.

The substrate 702 may be a piezoelectric substrate. The substrate 702 may be formed of lithium niobate.

The pair of IDT electrodes 704 may be formed on the substrate 702. Each of the pair of IDT electrodes 704 may have a comb-shape. Each of the pair of IDT electrodes 704 may include a bus bar 706 and a plurality of fingers 708 extending from the bus bar 706. According to an embodiment, the plurality of fingers 708 may extend from both sides of the bus bar 706. In FIG. 7A, the plurality of fingers 708 may extend in ±y direction from a particular bus bar. A respective finger of one IDT electrode may be arranged interleaved with respective fingers of the other IDT electrode.

The dielectric film 710 may cover the pair of IDT electrodes 704. The dielectric film 710 may be formed of oxide, particularly silicon dioxide, for example. In FIG. 7B, the thickness of the dielectric film 710 varies along the lines 7B-7B, due to the metal density of the bus bars 706. In this case, CMP process is necessary to remove the uneven surface of the dielectric film 710.

Hereinafter, an acoustic wave device that does not require CMP process according to an embodiment is provided.

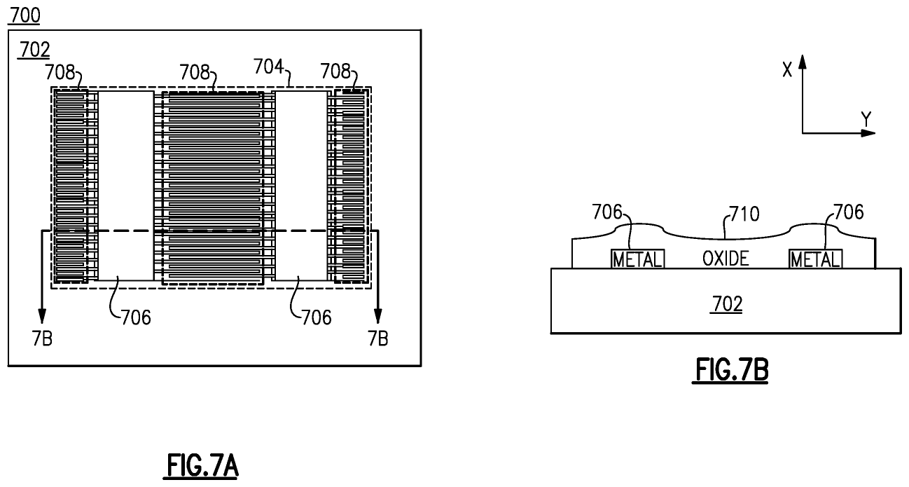

FIG. 8A is a schematic diagram of an example of an acoustic wave device 800 according to an embodiment. FIG. 8B is a schematic diagram of a cross-section of the acoustic wave device of FIG. 8A taken along the lines 8B-8B. As shown in FIGS. 8A, 8B, the acoustic wave device 800 includes a substrate 802, a pair of inter-digital transducer (IDT) electrodes 804, and a dielectric film 810.

The substrate 802 may be a piezoelectric substrate. The substrate 802 may be formed of lithium niobate.

The pair of IDT electrodes 804 may be formed on the substrate 802. Each of the pair of IDT electrodes 804 may have a comb-shape. Each of the pair of IDT electrodes 804 may include a bus bar 806 and a plurality of fingers 808 extending from the bus bar 806. According to an embodiment, the plurality of fingers 808 may extend from both sides of the bus bar 806. In FIG. 8A, the plurality of fingers 808 may extend in ±y direction from a particular bus bar. A respective finger of one IDT electrode may be arranged interleaved with respective fingers of the other IDT electrode.

Each of the bus bars 806 of the pair of IDT electrodes 804 may have a slotted portion 812. In this description, it is construed that the term ‘slotted portion’ does not only mean a single slot, but also means a set of slots. As will be described in more details, in case of an embodiment including a plurality of slots, the slotted portion may indicate the plurality of slots.

The slotted portion 812 may be configured on upper surface of the bus bars 806 that is opposite to a lower surface contacting the substrate 802. The slotted portion 812 may include at least one hollow within each of the bus bars 806. Thus, the hollow within each of the bus bars 806 may be opened at least at the upper surface of each of the bus bars 806. In other words, the upper surface of each of the bus bars 806 may have the slotted portion 812 that extends from the upper surface toward the lower surface within each of the bus bars 806. The hollow is the slotted portion 812 may be one-side opened shape, or two-side opened that is penetrating the bus bars from the upper side to the lower side. The slotted portion 812 may be a form of trench, silt, etching, for example. As will be described, the dielectric film 810 may fill in the hollow of the slotted portion 812, and therefore the dielectric film 810 may have more planar surface after oxide deposition that does not require CMP process.

According to an embodiment, the slotted portion 812 may include a plurality of slots extending in parallel to each other. In one example, each of the plurality of slots may extend in a direction that is same as an extending direction of the plurality of fingers 808. Referring to FIG. 8A, the plurality of slots may extend in ±y direction that is identical to the extending direction of the plurality fingers 808 extending in ±y direction. In another example, each of the plurality of slots may extend in a direction that is orthogonal to the extending direction of the plurality of fingers 808. More specifically, the plurality of slots may extend in ±x direction whereas the plurality fingers 808 extends in ±y direction.

In this embodiment, a distance between the adjacent slots among the plurality of slots may be substantially identical to a width of each of the plurality of fingers 808. The width of each of the plurality of fingers 808 may be defined in a direction that is orthogonal to an extending direction of the plurality of fingers 808. In this description, the term ‘substantially’ can be construed as to cover the variations or errors which can be incurred during the manufacturing process.

In this embodiment, a width of each of the plurality of slots may be substantially identical to a pitch distance of respective fingers of the pair of IDT electrodes 804. The width of each of the plurality of slots may be defined in a direction that is orthogonal to an extending direction of the plurality of slots. The pitch distance may be a distance between one finger of one IDT electrode and an adjacent finger of the other IDT electrode.

According to the embodiments, the dielectric film 810 may have an even upper surface throughout the pair of IDT electrodes 804, by configuring the slotted portion 812 with the same structure as the plurality of fingers 808. In addition, the contact area of the bus bars 806 and the dielectric film 810 may be increased and adhesion between the bus bars 806 and the plurality fingers 808 can be improved. Furthermore, the bus bars 806 can be designed to have different resistances depending on the extent of the slotted portion 812.

According to an embodiment, a remaining portion of the upper surface of each of the bus bars 806 other than the slotted portion 812 may be configured to be a part of a line that extends with a same width of each of the plurality of fingers 804. The remaining portion of the upper surface of each of the bus bars 806 may be an outline of each of the bus bars 806. In FIG. 8A, the outline of each of the bus bars 806 may be a square shape.

According to an embodiment, the slotted portion 812 may extend from the upper surface to the lower surface of each of the bus bars, such that at least a portion of the dielectric film 810 contacts the substrate 812. Since the slotted portion 812 is penetrating through each of the bus bars 806, the dielectric film 810 deposited on the IDT electrodes 804 may fill in the hollow of the slotted portion 812 and eventually touch the upper surface of the substrate 802.

The hollow of the slotted portion 812 may be grooved in square shape within the bus bars 806. For example, the slotted portion 812 may be configured by an etching process. The hollow can be made in a similar structure of a gap between the plurality of fingers 808. Therefore, the dielectric film 810 may fill in the gap between the plurality of fingers 808 similarly to the dielectric film 810 filling in the slotted portion 812.

According to an embodiment, the number of slots of the slotted portion 812 is not limited to a specific example. Thus, the slotted portion 812 may have a single slot. For example, the slotted portion 812 may be a single pulse-shaped slot (or zigzag slot). Even in this case, the single slot may have the same width as each of the plurality of fingers 808. In addition, the pulse-shaped slot may have a gap corresponding to a pitch distance of respective fingers 808 of the pair of IDT electrodes 804. The gap of the pulse-shape slot may be understood as a distance between parallel portions of the slot.

The dielectric film 810 may cover the pair of IDT electrodes 804. Alternatively, the dielectric film 810 may further cover at least a portion of the substrate 802. The dielectric film 810 may be formed of oxide, particularly silicon dioxide, for example. According to an embodiment, the dielectric film 810 may be configured to fill in the hollow of the slotted portion 812 during the oxide deposition process.

Thus, the thickness variation of the oxide layer may be constant throughout the acoustic wave device by configuring the bus bars to have a similar structure as the area in which the plurality of fingers are disposed.

This process does not require additional process steps and accomplishes improved adhesion, which in turn results in lower cost and improved reliability and performance.

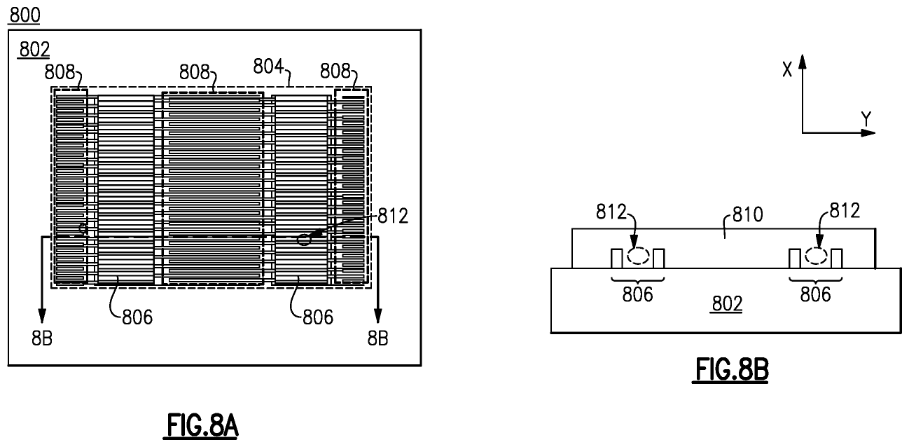

FIG. 9A is a schematic diagram of one embodiment of a packaged module 900. FIG. 9B is a schematic diagram of a cross-section of the packaged module 1000 of FIG. 9A taken along the lines 9A-9B.

The packaged module 900 includes an IC or die 901, surface mount components 903, wirebonds 908, a package substrate 920, and encapsulation structure 940. The package substrate 920 includes pads 906 formed from conductors disposed therein. Additionally, the die 901 includes pads 904, and the wirebonds 908 have been used to electrically connect the pads 904 of the die 901 to the pads 906 of the package substrate 901.

The die 901 includes a filter module, which can be implemented in accordance with any of the embodiments herein.

The packaging substrate 920 can be configured to receive a plurality of components such as the die 901 and the surface mount components 903, which can include, for example, surface mount capacitors and/or inductors.

As shown in FIG. 9B, the packaged module 900 is shown to include a plurality of contact pads 932 disposed on the side of the packaged module 900 opposite the side used to mount the die 901. Configuring the packaged module 900 in this manner can aid in connecting the packaged module 900 to a circuit board such as a phone board of a wireless device. The example contact pads 932 can be configured to provide RF signals, bias signals, power low voltage(s) and/or power high voltage(s) to the die 901 and/or the surface mount components 903. As shown in FIG. 12B, the electrically connections between the contact pads 932 and the die 901 can be facilitated by connections 933 through the package substrate 920. The connections 933 can represent electrical paths formed through the package substrate 920, such as connections associated with vias and conductors of a multilayer laminated package substrate.

In some embodiments, the packaged module 900 can also include one or more packaging structures to, for example, provide protection and/or facilitate handling of the packaged module 900. Such a packaging structure can include overmold or encapsulation structure 940 formed over the packaging substrate 920 and the components and die(s) disposed thereon.

It will be understood that although the packaged module 900 is described in the context of electrical connections based on wirebonds, one or more features of the present disclosure can also be implemented in other packaging configurations, including, for example, flip-chip configurations.

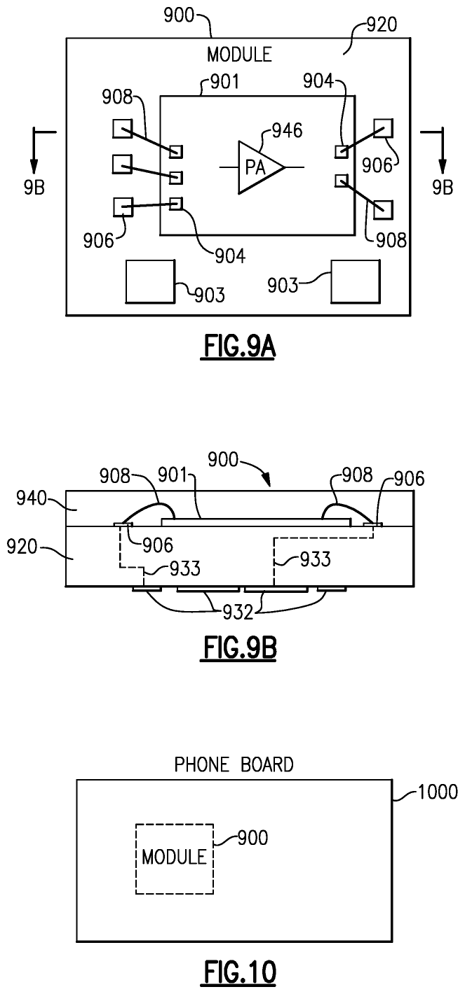

FIG. 10 is a schematic diagram of one embodiment of a phone board 1000. The phone board 1000 includes the module 900 shown in FIGS. 9A-9B attached thereto. Although not illustrated in FIG. 10 for clarity, the phone board 1000 can include additional components and structures.

### Applications

Some of the embodiments described above have provided examples in connection with wireless devices or mobile phones. However, the principles and advantages of the embodiments can be used for any other systems or apparatus that have needs for power amplifiers.

Such acoustic wave devices can be implemented in various electronic devices. Examples of the electronic devices can include, but are not limited to, consumer electronic products, parts of the consumer electronic products, electronic test equipment, etc. Examples of the electronic devices can also include, but are not limited to, memory chips, memory modules, circuits of optical networks or other communication networks, and disk driver circuits. The consumer electronic products can include, but are not limited to, a mobile phone, a telephone, a television, a computer monitor, a computer, a hand-held computer, a personal digital assistant (PDA), a microwave, a refrigerator, an automobile, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. An acoustic wave device comprising:
a substrate;
a pair of inter-digital transducer (IDT) electrodes formed on the substrate, each of the pair of IDT electrodes including a bus bar and a plurality of fingers extending from the bus bar, a respective finger of one IDT electrode arranged interleaved with respective fingers of the other IDT electrode, each of the bus bars of the pair of IDT electrodes having a slotted portion configured on an upper surface of the bus bars opposite to a lower surface contacting the substrate such that at least one hollow within each of the bus bars is opened at least at the upper surface of each of the bus bars; and
a dielectric film covering the pair of IDT electrodes, at least a portion of the dielectric film filling in the at least one hollow of each of the bus bars.

2. The acoustic wave device of claim 1 wherein the slotted portion includes a plurality of slots extending in parallel, and each of the plurality of slots extends in a direction same as an extending direction of the plurality of fingers.

3. The acoustic wave device of claim 1 wherein the slotted portion includes a plurality of slots extending in parallel, and each of the plurality of slots extends in a direction orthogonal to an extending direction of the plurality of fingers.

4. The acoustic wave device of claim 2 wherein a distance between the adjacent slots of the plurality of slots is substantially identical to a width of each of the plurality of fingers.

5. The acoustic wave device of claim 2 wherein a width of each of the plurality of slots is substantially identical to a pitch distance of respective fingers of the pair of IDT electrodes.

6. The acoustic wave device of claim 1 wherein a remaining portion of the upper surface of each of the bus bars other than the slotted portion is configured to be a part of a line with a same width of each of the plurality of fingers.

7. The acoustic wave device of claim 6 wherein the remaining portion of the upper surface of each of the bus bars is an outline of each of the bus bars.

8. The acoustic wave device of claim 1 wherein the slotted portion extends from the upper surface to the lower surface of each of the bus bars such that at least a portion of the dielectric film contacts with the substrate.

9. The acoustic wave device of claim 1 wherein the at least one hollow of the slotted portion is grooved in square shape within each of the bus bars.

10. The acoustic wave device of claim 1 wherein the slotted portion is a single pulse-shaped slot with a same width of each of the plurality of fingers and with a gap corresponding to a pitch distance of respective fingers of the pair of IDT electrodes therebetween.

11. The acoustic wave device of claim 1 wherein at least a portion of the dielectric film fills in a gap between the plurality of fingers of each of the pair of IDT electrodes, such that the dielectric film has a planar surface throughout the pair of IDT electrodes.

12. The acoustic wave device of claim 1 wherein the dielectric film is formed of silicon dioxide (SiO₂).

13. A radio frequency module comprising:
a packaging board configured to receive a plurality of components; and
an acoustic wave device implemented on the packaging board, the acoustic wave device including a substrate, a pair of inter-digital transducer (IDT) electrodes formed on the substrate, each of the pair of IDT electrodes including a bus bar and a plurality of fingers extending from the bus bar, a respective finger of one IDT electrode arranged interleaved with respective fingers of the other IDT electrode, each of the bus bars of the pair of IDT electrodes having a slotted portion configured on an upper surface of the bus bars opposite to a lower surface contacting the substrate such that at least one hollow within each of the bus bars is opened at least at the upper surface of each of the bus bars, and a dielectric film covering the pair of IDT electrodes, at least a portion of the dielectric film filling in the at least one hollow of each of the bus bars.

14. The radio frequency module of claim 13 wherein the radio frequency module is a front-end module.

15. The radio frequency module of claim 13 wherein the slotted portion includes a plurality of slots extending in parallel, and each of the plurality of slots extends in a direction orthogonal to an extending direction of the plurality of fingers.

16. The radio frequency module of claim 15 wherein a width of each of the plurality of slots is substantially identical to a pitch distance of respective fingers of the pair of IDT electrodes.

17. The radio frequency module of claim 13 wherein a remaining portion of the upper surface of each of the bus bars other than the slotted portion is configured to be a part of a line with a same width of each of the plurality of fingers.

18. The radio frequency module of claim 13 wherein the slotted portion extends from the upper surface to the lower surface of each of the bus bars such that at least a portion of the dielectric film contacts with the substrate.

19. The radio frequency module of claim 13 wherein the slotted portion is a single pulse-shaped slot with a same width of each of the plurality of fingers and with a gap corresponding to a pitch distance of respective fingers of the pair of IDT electrodes therebetween.

20. A mobile device comprising:
an antenna configured to receive a radio frequency signal; and
a front end system configured to communicate with the antenna, the front end system including an acoustic wave device having a substrate, a pair of inter-digital transducer (IDT) electrodes formed on the substrate, each of the pair of IDT electrodes including a bus bar and a plurality of fingers extending from the bus bar, a respective finger of one IDT electrode arranged interleaved with respective fingers of the other IDT electrode, each of the bus bars of the pair of IDT electrodes having a slotted portion configured on an upper surface of the bus bars opposite to a lower surface contacting the substrate such that at least one hollow within each of the bus bars is opened at least at the upper surface of each of the bus bars, and a dielectric film covering the pair of IDT electrodes, at least a portion of the dielectric film filling in the at least one hollow of each of the bus bars.
